(19) United States
(12) Patent Application Publication
(10) Pub. No.: US 2007/0020842 A1
(43) Pub. Date: Jan. 25, 2007

(54) Method of manufacturing mask ROM

(75) Inventors: Li Lang Tang, Hsinchu (TW); Shiu Fang Lo, Hsinchu (TW); Chon Shin Jou, Hsinchu (TW)

Correspondence Address: BACON & THOMAS, PLLC, 625 SLATERS LANE, FOURTH FLOOR, ALEXANDRIA, VA, 22314, US

(73) Assignee: MOSEL VITELIC INC., Hsinchu (TW)

(21) Appl. No.: 11/482,715

(22) Filed: Jul. 10, 2006

(30) Foreign Application Priority Data
Jul. 21, 2005 (TW) TW 094124776

(51) Int. Cl. H01L 21/8238

(52) U.S. Cl. 438/233

(57) ABSTRACT

A method of manufacturing a ROM is disclosed. The method comprises steps of (a) providing a substrate and forming a plurality of gate structures on said substrate, (b) forming a first oxide layer on said substrate and said plurality of gate structures, (c) forming a mask layer on said first oxide layer and partially etching said mask layer to form a writing opening, (d) performing an ion implantation process through said mask layer, (e) removing said mask layer to expose said first oxide layer, (f) forming a second oxide layer on said first oxide layer, (g) partially etching said second oxide layer and said first oxide layer to expose a part of said substrate as a contact opening, and (h) forming a metal layer on said contact opening. Thereby, the damage of the gate structure and the problem of metal line short can be effectively avoided.

### FIELD OF THE INVENTION

The present invention relates to a method of manufacturing a non-volatile memory, and more particularly to a method of manufacturing a mask read-only memory (mask ROM).

### BACKGROUND OF THE INVENTION

There are two kinds of the memory, which are the volatile memory and the non-volatile memory. The maintenance of the data in the volatile memory, such as the dynamic random access memory (DRAM) and the static random access memory (SRAM), depends on continuous power supply. On the contrary, the data in the non-volatile memory, such as the mask read-only memory (mask ROM), the erasable programmable read-only memory (EEPROM) and the flash memory, can be maintained for a long time after the power supply is interrupted.

The mask ROM, which is a kind of the non-volatile memory, uses a mask for defining a specific pattern in the manufacturing process, so as to write the data or program into the ROM once. The mask ROM has advantages of low cost, high reliability and large capacity, and thus, it is widely used in various information, communication and consumer electronic products as the storage device for storing the data of program, font, image and sound, etc., such as the voice ROM.

Please refer to FIGS. 1(A)-(E), which are schematic views showing the manufacturing processes of a conventional voice ROM. First, as shown in FIG. 1(A), a substrate 11 is provided and a plurality of gate structures 12 are formed on the substrate 11. Then, a first oxide layer 13, such as nondoped silica glass (NSG), is deposited on the substrate 11. Afterward, a second oxide layer 14, such as borophosphosilicate glass (BPSG), is deposited on the first oxide layer 13, and the resulted structure is shown in FIG. 1(B). Subsequently, the second oxide layer 14 and the first oxide layer 13 are partially etched to expose a part of the substrate 11 as a metal contact window 15, as shown in FIG. 1(C). After that, a ROM writing process is performed, in which a mask layer 16 is formed on the aforesaid structure and partially etched to define a ROM writing region 161, as shown in FIG. 1(D), wherein a height difference A is usually formed due to the overetch of the second oxide layer 14.

Further, an ion implantation process is performed through the mask layer 16 to complete the ROM writing process in the ROM writing region 161, and then the mask layer 16 is removed. Subsequently, a metal layer 17 is deposited and partially etched to form a conducting metal layer 17, as shown in FIG. 1(E). However, during this etching process, a further overetch usually happens, so that a layer B (shown as the dotted line) of the second oxide layer 14 is etched away. Since the second oxide layer 14 is etched twice during the ROM writing process and the metal layer etching process, respectively, the second oxide layer 14 might be etched through and the gate structure 12 might be damaged accordingly.

As described above, in the manufacturing processes of the conventional mask ROM, since the second oxide layer 14 is easily etched through due to the two etching processes, the gate structure 12 is easily damaged, and thus, the electrical property of the device is influenced. On the other hand, the height difference A of the second oxide layer 14 caused by the etching step of the ROM writing process will result in the galvanic phenomenon, and since the aluminum oxide residue is difficult to be removed, the metal line short might be caused. Therefore, it is needed to provide a method of manufacturing the ROM to overcome the defects of the prior art without increasing the equipment cost.

### SUMMARY OF THE INVENTION

An object of the present invention is to provide a manufacturing method of a mask ROM to overcome the defects of the prior art by adjusting and modifying the manufacturing processes thereof without increasing the equipment cost, so as to prevent the damage of the gate structure and the problem of metal line short.

According to an aspect of the present invention, a method of manufacturing a ROM is provided. The method comprises steps of (a) providing a substrate and forming a plurality of gate structures on the substrate, (b) forming a first oxide layer on the substrate and the plurality of gate structures, (c) forming a mask layer on the first oxide layer and partially etching the mask layer to form a writing opening, (d) performing an ion implantation process through the mask layer, (e) removing the mask layer to expose the first oxide layer, (f) forming a second oxide layer on the first oxide layer, (g) partially etching the second oxide layer and the first oxide layer to expose a part of the substrate as a contact opening, and (h) forming a metal layer on the contact opening.

According to another aspect of the present invention, a method of manufacturing a ROM is further provided. The method comprises steps of (a) providing a substrate and forming a plurality of gate structures on the substrate, (b) forming a first oxide layer on the substrate and the plurality of gate structures, (c) forming a first mask layer on the first oxide layer and partially etching the first mask layer to form a first writing opening, (d) performing a first ion implantation process through the first mask layer, (e) removing the first mask layer to expose the first oxide layer, (f) forming a second mask layer on the first oxide layer and partially etching the second mask layer to form a second writing opening, (g) performing a second ion implantation process through the second mask layer, (h) removing the second mask layer to expose the first oxide layer, (i) forming a second oxide layer on the first oxide layer, (j) partially etching the second oxide layer and the first oxide layer to expose a part of the substrate as a contact opening, and (k) forming a metal layer on the contact opening.

The above objects and advantages of the present invention will become more readily apparent to those ordinarily skilled in the art after reviewing the following detailed description and accompanying drawings, in which:

### BRIEF DESCRIPTION OF THE DRAWINGS

FIGS. 1(A)-(E) are schematic views showing the manufacturing processes of a conventional voice ROM;

FIGS. 2(A)-(E) are schematic views showing the manufacturing processes of the mask ROM according to a preferred embodiment of the present invention; and

FIGS. 3(A)-(F) are schematic views showing the manufacturing processes of the mask ROM according to another preferred embodiment of the present invention.

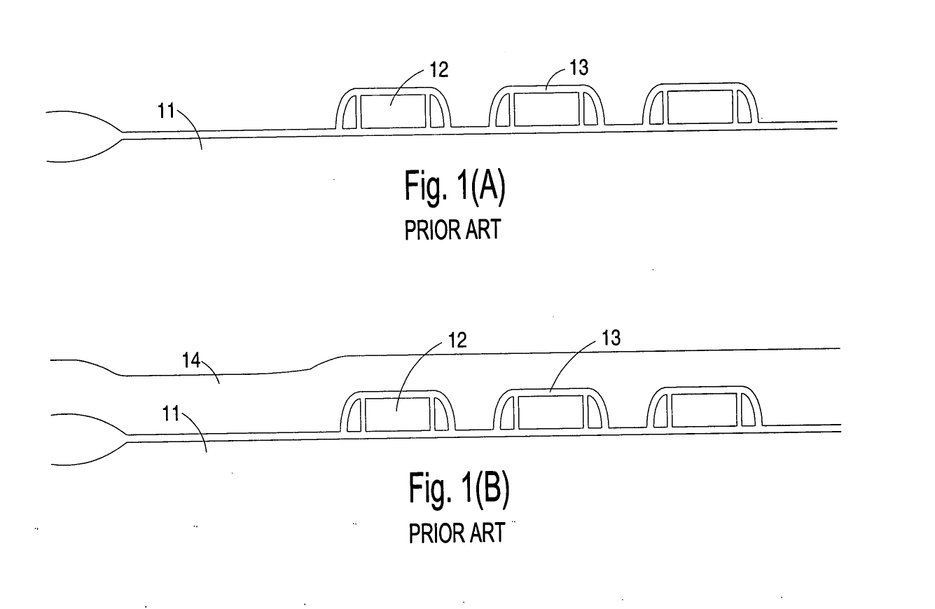

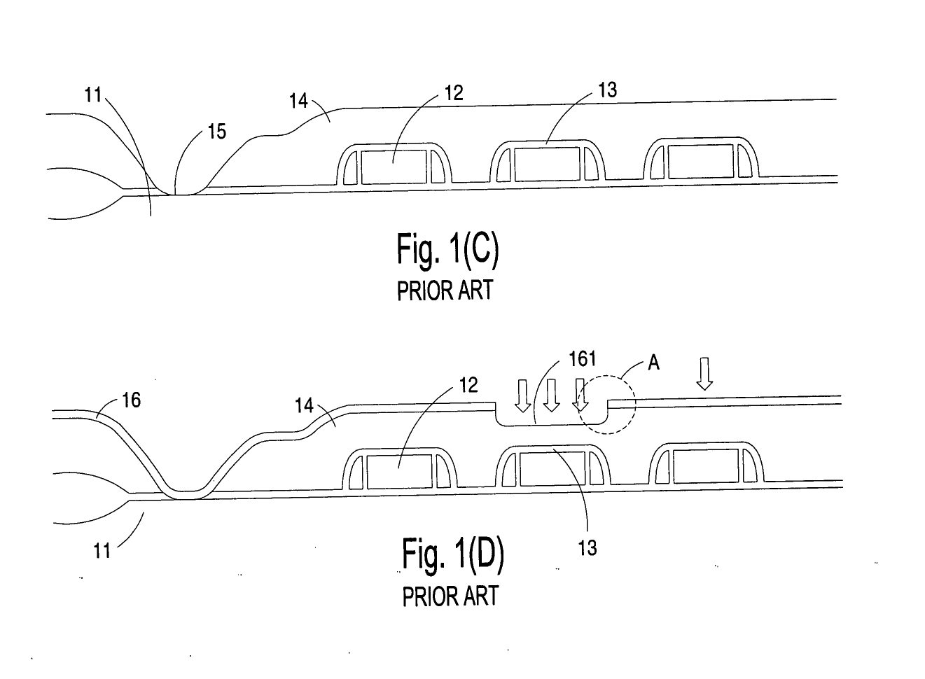

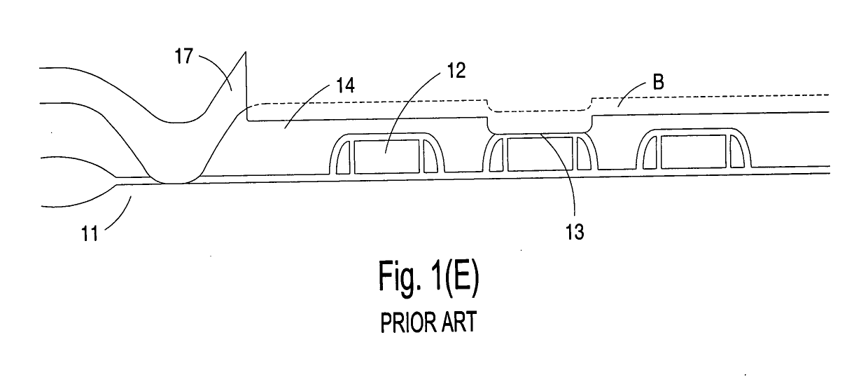

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

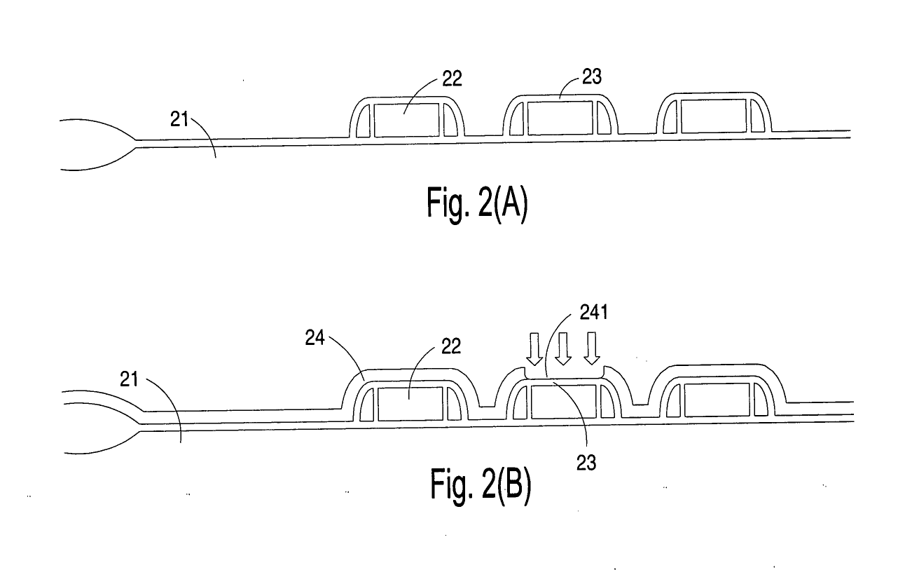

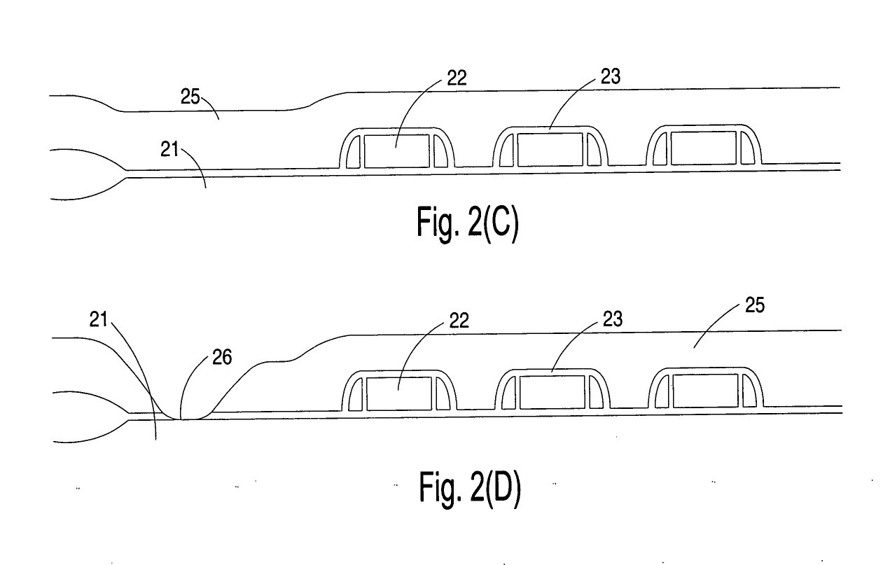

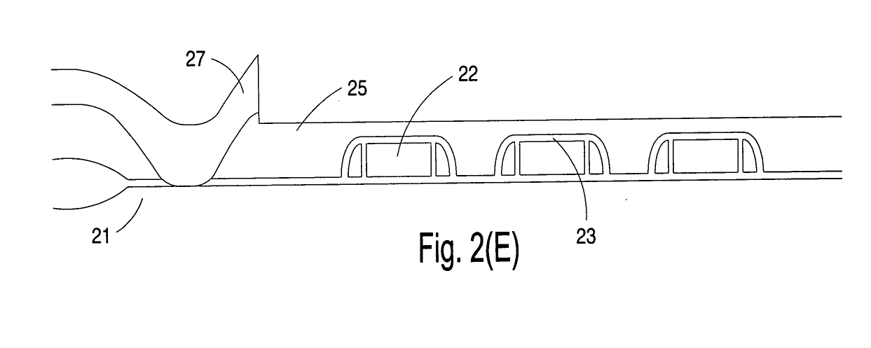

Please refer to FIGS. 2(A)-(E), which are schematic views showing the manufacturing processes of the mask ROM according to a preferred embodiment of the present invention. First, as shown in FIG. 2(A), a substrate 21 is provided and a plurality of gate structures 22 are formed on the substrate 21. Then, a first oxide layer 23 is formed on the substrate 21 and the gate structures 22 to cover the substrate 21 and the gate structures 22. The first oxide layer 23 can be a nondoped oxide layer, such as nondoped silica glass (NSG).

Later, a ROM writing process is performed. As shown in FIG. 2(B), a mask layer 24 is formed on the first oxide layer 23 and partially etched by a lithographic etching process to form a writing opening 241, and then, using the mask layer 24 as a mask, an ion implantation process is performed through the writing opening 241 to implant ions into a gate channel (not shown), so as to complete the ROM writing process. Afterward, the mask layer 24 is removed to expose the first oxide layer 23. Then, a second oxide layer 25 is deposited on the first oxide layer 23, and the resulted structure is shown in FIG. 2(C), wherein the second oxide layer 25 can be an oxide layer doped with boron and phosphate, such as borophosphosilicate glass (BPSG). Subsequently, the second oxide layer 25 and the first oxide layer 23 are partially etched via an anisotropic etching process to expose a part of the substrate 21 as a metal contact opening 26, as shown in FIG. 2(D). Finally, a metal layer 27 is formed to cover the second oxide layer 25 and the metal contact opening 26, and the metal layer 27 is partially etched by a lithographic etching process to form a conducting metal layer 27 on the metal contact opening 26, as shown in FIG. 2(E). Thereby, the defects of the prior art can be avoided, and the damage of the gate structure and the problem of metal line short will not happen.

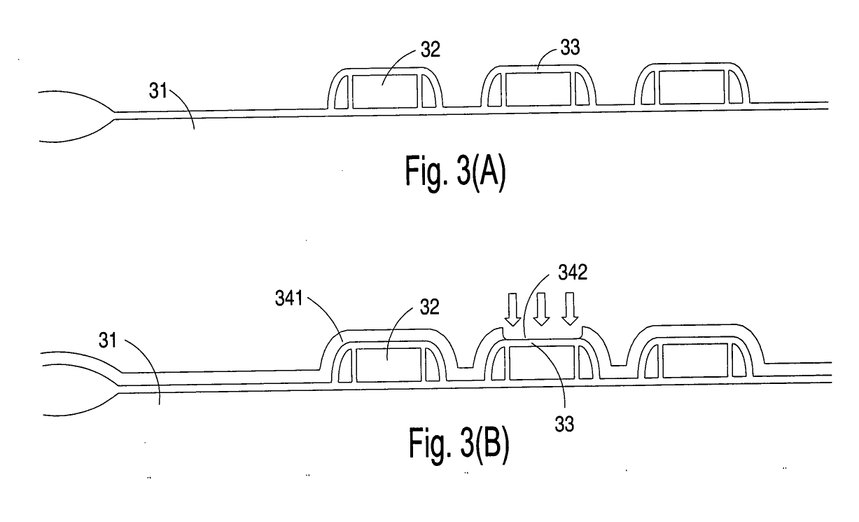

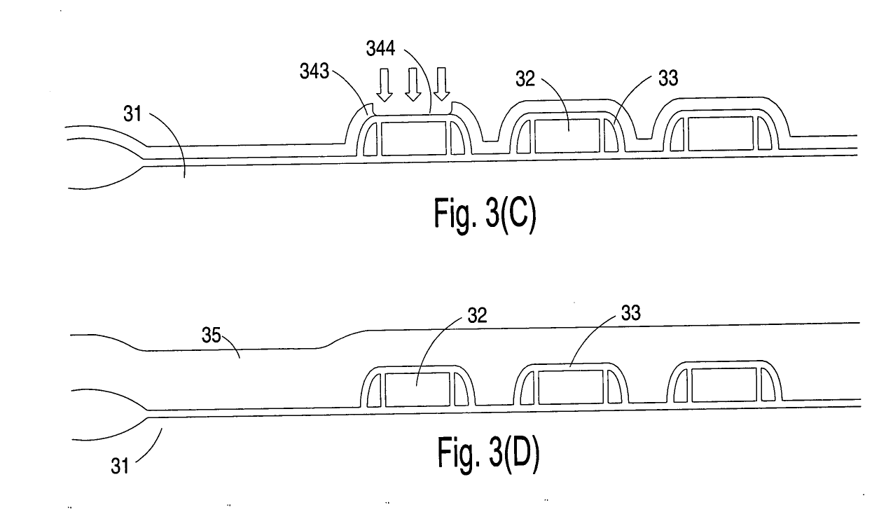

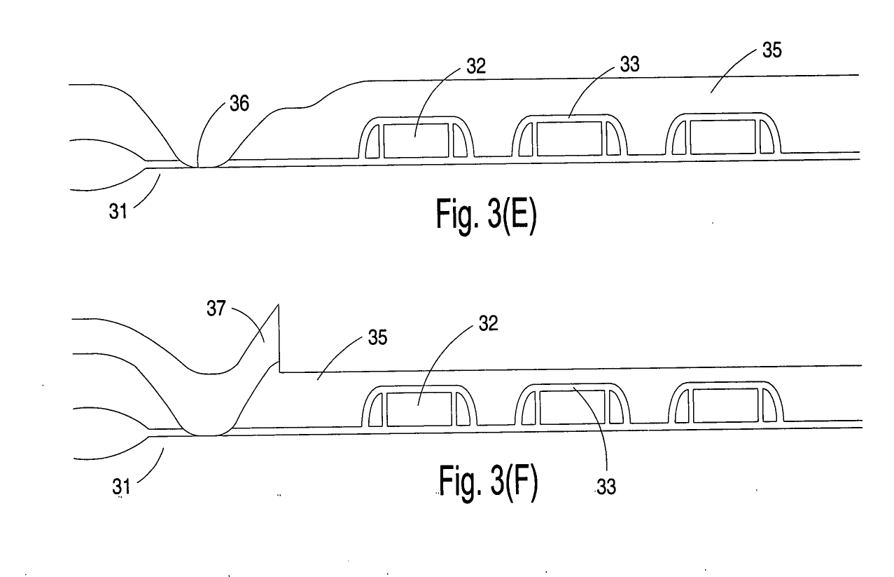

Please refer to FIGS. 3(A)-(F), which are schematic views showing the manufacturing processes of the mask ROM according to another preferred embodiment of the present invention. First, as shown in FIG. 3(A), a substrate 31 is provided and a plurality of gate structures 32 are formed on the substrate 31. Then, a first oxide layer 33 is formed on the substrate 31 and the gate structures 32 to cover the substrate 31 and the gate structures 32. The first oxide layer 23 can be a nondoped oxide layer, such as nondoped silica glass (NSG). Afterward, a first mask layer 341 is formed on the first oxide layer 33 and partially etched to form a first writing opening 342, as shown in FIG. 3(B), and then, using the first mask layer 341 as a mask, a first ion implantation process is performed through the first writing opening 342 to implant ions with first doping amount into a gate channel, so as to complete the first ROM writing process. After that, the first mask layer 341 is removed to expose the first oxide layer 33.

A second ROM writing process is further performed. As shown in FIG. 3(C), a second mask layer 343 is formed on the first oxide layer 33 and partially etched to form a second writing opening 344, and then, using the second mask layer 343 as a mask, a second ion implantation process is performed through the second writing opening 344 to implant ions with second doping amount into another gate channel, so as to complete the second ROM writing process. Also, the second mask layer 343 is removed to expose the first oxide layer. Different from the former embodiment, this embodiment includes two ROM writing processes.

Later, a second oxide layer 35 is deposited on the first oxide layer 33, as shown in FIG. 3(D), wherein the second oxide layer 35 can be an oxide layer doped with boron and phosphate, such as borophosphosilicate glass (BPSG). Subsequently, the second oxide layer 35 and the first oxide layer 33 are partially etched via an anisotropic etching process to expose a part of the substrate 31 as a metal contact opening 36, as shown in FIG. 3(E). Finally, a metal layer 37 is formed to cover the second oxide layer 35 and metal contact opening 36, and the metal layer 37 is partially etched by a lithographic etching process to form a conducting metal layer 37 on the metal contact opening 36, as shown in FIG. 3(F). Thereby, the defects of the prior art can be avoided, and the damage of the gate structure and the problem of metal line short will not happen.

In conclusion, the present invention provides a method of manufacturing a mask ROM, which adjusts the mask layer forming step to before the deposition of the second oxide layer, so that the gate structure can be prevented from being damaged due to the overetch of the second oxide layer. Moreover, the planarity of the metal layer can be increased, so as to avoid the galvanic phenomenon and the problem that the aluminum oxide residue is difficult to be removed. Therefore, by the above modifications of the manufacturing processes and without the increase of the equipment cost, the defects of the conventional mask ROM can be overcome, and the damage of the gate structure during the conventional manufacturing processes of the mask ROM and the problem of metal line short can be effectively avoided.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method of manufacturing a read-only memory (ROM), comprising steps of:
(a) providing a substrate and forming a plurality of gate structures on said substrate;
(b) forming a first oxide layer on said substrate and said plurality of gate structures;
(c) forming a mask layer on said first oxide layer and partially etching said mask layer to form a writing opening;
(d) performing an ion implantation process through said mask layer;
(e) removing said mask layer to expose said first oxide layer;
(f) forming a second oxide layer on said first oxide layer;
(g) partially etching said second oxide layer and said first oxide layer to expose a part of said substrate as a contact opening; and
(h) forming a metal layer on said contact opening.

2. The method of manufacturing the ROM according to claim 1 wherein said ROM is a mask ROM.

3. The method of manufacturing the ROM according to claim 1 wherein said ROM is a voice ROM.

4. The method of manufacturing the ROM according to claim 1 wherein said first oxide layer is a nondoped oxide layer.

5. The method of manufacturing the ROM according to claim 4 wherein said first oxide layer is nondoped silica glass (NSG).

6. The method of manufacturing the ROM according to claim 1 wherein said second oxide layer is an oxide layer doped with boron and phosphate.

7. The method of manufacturing the ROM according to claim 6 wherein said second oxide layer is borophosphosilicate glass (BPSG).

8. The method of manufacturing the ROM according to claim 1 wherein said step (d) is a ROM writing process.

9. The method of manufacturing the ROM according to claim 1 wherein said step (g) is an anisotropic etching process.

10. The method of manufacturing the ROM according to claim 1 wherein said step (h) further comprises steps of:
(h1) depositing a metal layer on said second oxide layer and said contact opening; and
(h2) performing a lithographic etching process to partially etch said metal layer and form a conducting metal layer on said contact opening.

11. A manufacturing method of a read-only memory (ROM), comprising steps of:
(a) providing a substrate and forming a plurality of gate structures on said substrate;
(b) forming a first oxide layer on said substrate and said plurality of gate structures;
(c) forming a first mask layer on said first oxide layer and partially etching said first mask layer to form a first writing opening;
(d) performing a first ion implantation process through said first mask layer;
(e) removing said first mask layer to expose said first oxide layer;
(f) forming a second mask layer on said first oxide layer and partially etching said second mask layer to form a second writing opening;
(g) performing a second ion implantation process through said second mask layer;
(h) removing said second mask layer to expose said first oxide layer;
(i) forming a second oxide layer on said first oxide layer;
(j) partially etching said second oxide layer and said first oxide layer to expose a part of said substrate as a contact opening; and
(k) forming a metal layer on said contact opening.

12. The method of manufacturing the ROM according to claim 11 wherein said ROM is a mask ROM.

13. The method of manufacturing the ROM according to claim 11 wherein said ROM is a voice ROM.

14. The method of manufacturing the ROM according to claim 11 wherein said first oxide layer is a nondoped oxide layer.

15. The method of manufacturing the ROM according to claim 14 wherein said first oxide layer is nondoped silica glass (NSG).

16. The method of manufacturing the ROM according to claim 11 wherein said second oxide layer is an oxide layer doped with boron and phosphate.

17. The method of manufacturing the ROM according to claim 16 wherein said second oxide layer is borophosphosilicate glass (BPSG).

18. The method of manufacturing the ROM according to claim 11 wherein said step (d) is a first ROM writing process.

19. The method of manufacturing the ROM according to claim 18 wherein said step (g) is a second ROM writing process.

20. The method of manufacturing the ROM according to claim 11 wherein said step (j) is an anisotropic etching process.

21. The method of manufacturing the ROM according to claim 11 wherein said step (k) further comprises steps of:
(k1) depositing a metal layer on said second oxide layer and said contact opening; and
(k2) performing a lithographic etching process to partially etch said metal layer and form a conducting metal layer on said contact opening.
